(19) United States
(12) Patent Application Publication
(10) Pub. No.: US 2012/0262191 A1
(43) Pub. Date: Oct. 18, 2012

(54) EXTENSION SENSOR AND METHOD FOR MEASURING AN EXTENSION OF A TEXTILE

(75) Inventors: Ivo Locher, Zug (CH); Sebastian Rumpf, Thal (CH)

(73) Assignee: SEFAR AG, Heiden (CH)

(21) Appl. No.: 13/247,767

(22) Filed: Sep. 28, 2011

(30) Foreign Application Priority Data
Oct. 18, 2010 (EP) 10013726.4

(51) Int. Cl. G01R 27/26

(52) U.S. Cl. 324/658

(57) ABSTRACT

The invention relates to an extension sensor, in particular for measuring an extension of a textile, comprising at least one yarn, which has an extensibility and wherein the yarn comprises at least two electrically conductive layers that extend along a longitudinal direction of the yarn, wherein the electrically conductive layers are spatially separated and insulated from each other.

The invention relates to an extension sensor, in particular for measuring an extension of a textile, according to the preamble of claim 1. Furthermore, the invention relates to a method for measuring an extension of a textile according to the preamble of claims 12 and 13.

To measure the extension of an object different kinds of extension sensors, such as displacement sensors or strain gauges, are known.

The invention is based on the object to provide an extension sensor and a method for measuring an extension of a textile, which enable easy and precise determination of the extension of an object, in particular a textile.

The object is solved in a first aspect by an extension sensor having the features of claim 1 and in a second aspect by a method having the features of claims 12 and 13. Preferred embodiments and variants of the invention are stated in the dependent claims.

The extension sensor according to the invention is characterized in that at least one yarn is provided, which has an extensibility, and in that the yarn comprises at least two electrically conductive layers which extend along a longitudinal direction of the yarn, wherein the electrically conductive layers are spatially separated and insulated from each other.

A fundamental idea of the invention resides in the fact that the extension sensor is designed in the form of yarn. Hence, the yarn itself, which can basically also be a component of the textile, the extension of which is to be measured, forms at least a part of the extension sensor.

Another fundamental idea of the invention resides in the fact that for determination of the extension use is made of a change of an electrical property of the yarn caused by the extension of the yarn. For this purpose the yarn has at least two electrically conductive layers. The electrical property can, in particular, be a capacity or an electrical conductivity or respectively a specific electrical resistance. The change of the electrical property can be measured by a connected measuring instrument.

A further fundamental idea of the invention can be seen in the fact that on a single yarn provision is made for at least two, in particular precisely two, electrically conductive layers, the electrical property of which is drawn upon for determining the extension. By providing two electrically conductive layers on a single yarn the yarn can be employed for different measuring principles. Moreover, a particular advantage of the at least two conductive layers resides in the fact that for measurement of the extension the measuring instrument only has to be connected to precisely one longitudinal end of the yarn, i.e. it does not have to contact the opposite longitudinal ends of the yarn. As a result, a comfortable measurement possibility is created.

A preferred embodiment of the extension sensor according to the invention resides in the fact that by means of the electrically conductive layers a capacitor is formed, the capacity of which changes in the case of an extension of the yarn due to a change of distance between the electrically conductive layers. This embodiment is therefore concerned with a capacitive extension sensor. The measuring principle resides in determining the extension through an electrical capacity of a capacitor. If the yarn is extended, its cross-section decreases and the electrically conductive layers, that each form an electrode of the capacitor, approach each other. Consequently, in the case of an extension of the yarn the mutual distance of the electrically conductive layers is reduced. This leads to an increase in the electrical capacity of the capacitor, from which the extension of the textile can be determined. Conversely, a contraction of the yarn leads to an increase in the distance and consequently to a reduction of the capacity.

To determine the extension of the textile a measuring instrument can be connected to the extension sensor or measurement transducer formed by the at least one yarn. Extension sensor and measuring instrument constitute a measuring means. For extension measurement the measuring instrument is connected to both electrically conductive layers. Since these are present in any chosen part of the yarn, the measuring instrument can also be connected at any position of the yarn. This offers the advantage that the measuring instrument can be connected to a single, defined length portion, for example to a single axial end of the yarn. If the yarn is incorporated into a textile, the measuring instrument can be connected to a single edge region of the textile. A comparatively complicated contacting of different edges of the textile is not required.

Moreover, the capacitive extension sensor offers the advantage that the two conductive layers of the yarn forming the electrodes of the capacitor do not have to be short-circuited. Thus, the extension sensor can be formed in a simple manner solely by introducing the yarn into the textile.

In an alternative embodiment of the invention provision is made that between the electrically conductive layers a conductor link is arranged and that by means of the electrically conductive layers a conductor path is formed, the electrical resistance of which changes in the case of an extension of the yarn due to an elongation of the conductor path. This embodiment is therefore concerned with a resistive extension sensor. The measuring principle resides in determining the extension through an ohmic resistance of the conductive layers. In contrast to the capacitive extension sensor provision is made for the electrically conductive layers to be short-circuited via a conductor link, by preference at an axial end of the yarn. For extension measurement a measuring instrument is connected to the opposite end of the yarn so that a closed circuit is formed by the two conductive layers and the measuring instrument. If the yarn is extended, ohmic resistance of the conductive layers changes. From this change the extension of the textile can be determined.

For a precise measurement of the extension of the textile it is preferred that the yarn has a reversible extensibility. This is to be understood as meaning that the yarn, after having been extended, resumes its original shape. By preference, the yarn is designed such that minimal hysteresis occurs during the reversible extension.

For an advantageous measurement of the extension of a textile the reversible extensibility preferably amounts to 2 to 10%, more preferably 5 to 10% and more preferably 2 to 5%.

By a yarn any kind of elongate, textile structure is understood in the present case. The yarn can have one or more fibers. Basically, the cross-section of the yarn can be of any chosen design. However, it is especially preferred that the yarn has a round or rectangular cross-section. A yarn with a round cross-section is particularly easy to incorporate into a textile. The textile can be a woven fabric, a weft-knitted or a warp-knitted fabric in particular. A yarn having a rectangular cross-section, which can also be referred to as tape or ribbon, is particularly suitable for application in other two-dimensional structures, such as film. The tape or ribbon can have a width in the ranging from 0.05 to 0.2 mm, in particular approximately 0.1 mm.

The two electrically conductive layers are electrically insulated from each other along the length of the yarn. For this purpose an insulator is provided that separates the layers from each other. In a preferred embodiment the yarn comprises a polymer as insulator. In particular, this can be polyethylene terephthalate (PET), polyetherether ketone (PEEK), polyamide (PA), polyimide (PI) and/or polyphenylene sulfide (PPS).

By preference, the insulator constitutes a carrier of the yarn that substantially gives the yarn its mechanical properties, especially its flexibility, tensile strength and/or extensibility.

It is preferred that the insulator and the conductive layers have the same or a similar modulus of elasticity.

In a preferred embodiment at least one of the conductive layers is provided as a conductive, in particular thin coating of the insulator or carrier. By preference, the conductive layers contain silver, copper, gold and/or carbon. The conductive layers can also be formed by a filled polymer or a conducting polymer.

Especially for the application as a capacitive extension sensor the conductivity does not need to be very high. It is preferred that the conductive layers each have an electrical resistance of 0.1 to 2 kOhm/m (0.1 to 2 kΩ/m).

In a preferred embodiment of the yarn the conductive layers are each provided on an outer surface of the yarn. Hence, the conductive layers are arranged at least partially around a central carrier forming the insulator. In the case of a yarn having a round cross-section it is preferred that the conductive layers are designed in the shape of a channel or half-shell. The conductive layers are preferably arranged opposite each other along the longitudinal direction of the yarn around the central insulator and are separated from each other by way of intermediate spaces extending along the longitudinal direction. Consequently, the conductive layers preferably have an approximately semi-circular cross-section. If the yarn is designed with a rectangular cross-section the conductive layers can be designed as plane, two-dimensional layers.

If the yarn is designed with a round cross-section the insulator can be of cylindrical shape. Alternatively, it is also possible that the insulator has a different shape, for example a rectangular shape, and that the cylindrical shape of the yarn is only brought about by the combination of insulator and conductive layers.

An especially easy production of the external conductive layers can be achieved in that the insulator or carrier is of substantially cylindrical design, wherein two groove-like recesses or cavities are designed along a longitudinal direction of the insulator or carrier. In this way, a conductive coating can be applied onto an outer surface of the insulator or carrier, in which case the recesses or cavities render it possible for two conductive layers that are separate and insulated from each other to be formed automatically during the production process. Hence, the recesses or cavities separate the two electrically conductive layers from each other.

Another preferred embodiment of the yarn is provided in that the conductive layers are arranged coaxially to each other, wherein a first conductive layer is arranged in an inner region of the yarn and a second conductive layer is arranged in an outer region of the yarn. Such a coaxial yarn is easy to produce, offering a secure electrical insulation of the two electrical layers with respect to each other. Between the conductive layers a cylindrical insulator is arranged.

In a further preferred embodiment a protective coating for protection against abrasion and/or humidity is present. By preference, the protective coating is provided on an outer surface of the yarn. Moreover, an electrically insulating external coating of the yarn can be provided, too. Protective coating and insulating coating can also be formed by a single coating.

In a preferred embodiment of the extension sensor a textile is provided, into which the yarn is incorporated, in particular through weaving or knitting, in addition to other yarns. The textile itself therefore forms part of the extension sensor. In another preferred embodiment several corresponding yarns are incorporated into the textile. The yarns can be arranged in the warp and/or weft direction. Basically, it is also possible for the entire textile to consist of such yarns.

The method in accordance with the invention for measuring an extension of a textile is characterized in that at least one extensible yarn is made available, which comprises at least two electrically conductive layers that extend along a longitudinal direction of the yarn, in particular parallel to each other, wherein the electrically conductive layers are spatially separated and insulated from each other, and in that for determining an extension of the textile a change of the capacity of a capacitor formed by the conductive layers or a change of the electrical resistance of a conductor path formed by the conductive layers is measured.

For implementation of the method use can be made, in particular, of an extension sensor as described in the foregoing. The afore-described extension sensor is particularly suitable for use in the method according to the invention.

To measure the extension of the textile a measuring instrument can be connected to the yarn, especially to an edge region of the textile. The unit consisting of extension sensor and measuring instrument forms a measuring means. On measuring the capacity of the capacitor formed by the conductive layers a further contacting of the electrically conductive layers is not intended. To measure the electrical resistance the conductive layers are electrically connected via a conductor link at the end of the textile lying opposite the measuring instrument in order to form a circuit. As a result of the U-shaped arrangement of the conductor path thus formed the measuring instrument can be connected to one side of the textile and does not have to contact opposite lying sides of the textile.

An alternative method for measuring an extension of the textile is characterized in that at least two extensible yarns are made available, which each have an electrically conductive layer, in that the yarns are incorporated into the textile, in that on a first side of the textile a conductor link is arranged between the yarns so that a conductor path is formed by the yarns and in that for determining an extension of the textile a change of the electrical resistance of the conductor path formed by the yarns is measured on a second side of the textile.

Thus, in this method yarns can be employed which only have a single electrically conductive layer. To form a U-shaped conductor path two yarns each are connected to each other on one end so that on the opposite end a measuring instrument for measuring the electrical resistance of the conductor path can be connected.

An improvement of sensitivity can be achieved if the electrically conductive layers or yarns are connected to each other in a loop-like manner in order to form a circuit. To this end the yarns can be connected to each other in each case at end regions via conductor links.

As conductor links any type of electrical connection is basically suitable. The conductive layers or yarns can be connected to each other via cable links for example. Furthermore, the insulator can be removed at an end region of a yarn so as to connect the conductive layers of the yarn with each other.

In a preferred embodiment of the method provision is made for the extensible yarns to be incorporated into the textile, in particular through weaving or knitting. As a result, the advantages described in conjunction with the extension sensor are achieved.

In the following the invention is described further by way of preferred embodiments illustrated in the accompanying schematic drawings, wherein show:

FIG. 1 a perspective view of a first embodiment of an extension sensor according to the invention;

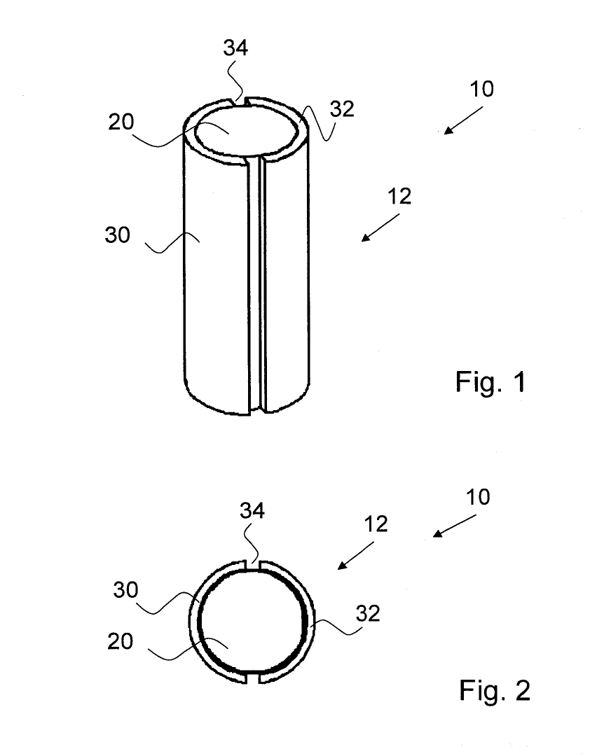

FIG. 2 a cross-sectional view of the extension sensor of FIG. 1;

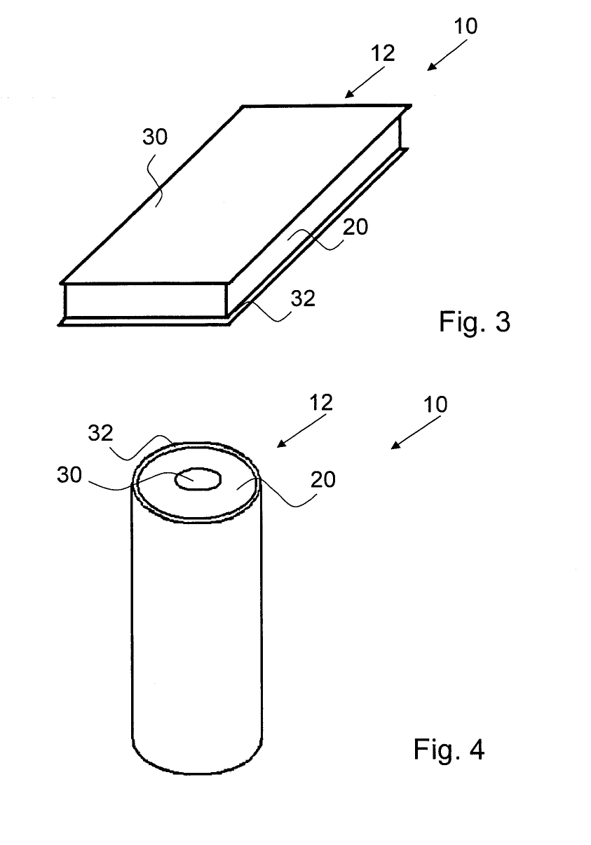

FIG. 3 a perspective view of a second embodiment of an extension sensor according to the invention;

FIG. 4 a perspective view of a third embodiment of an extension sensor according to the invention;

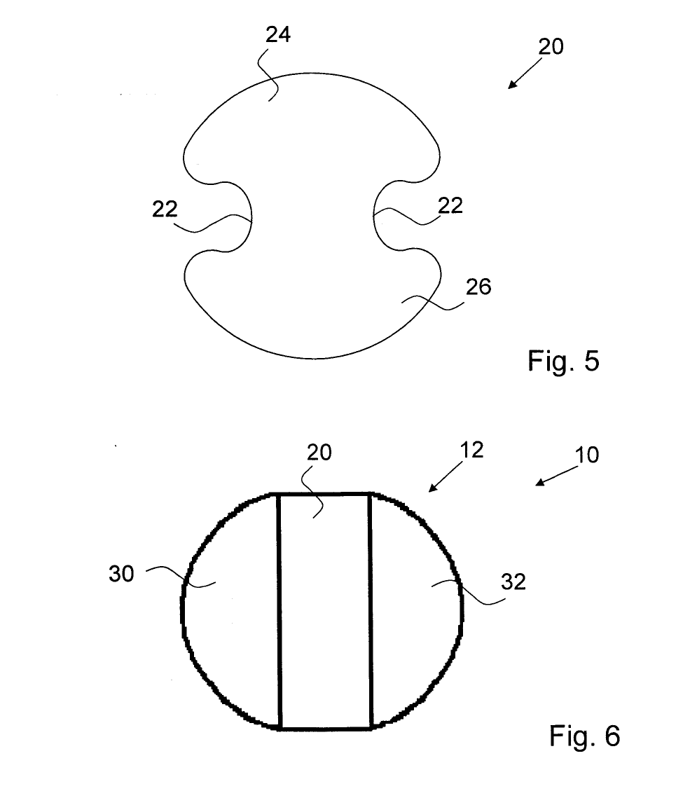

FIG. 5 a cross-sectional view of an insulator of an extension sensor according to the invention;

FIG. 6 a cross-sectional view of a fourth embodiment of an extension sensor according to the invention and

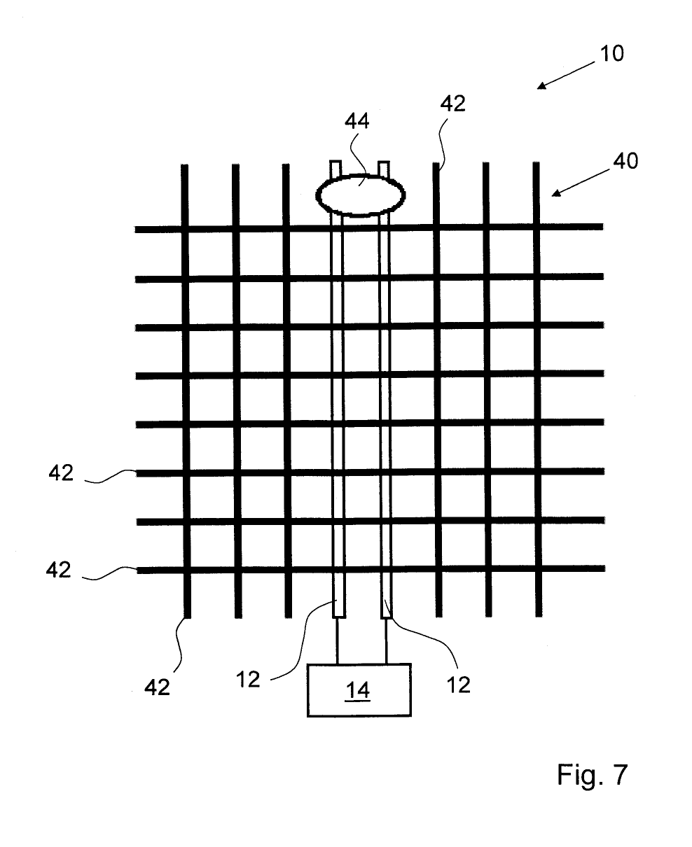

FIG. 7 a fifth embodiment of an extension sensor according to the invention.

A first embodiment of an extension sensor 10 according to the invention in the form of yarn is shown in FIGS. 1 and 2. The extension sensor 10 comprises an extensible yarn 12, which can also be referred to as a measuring yarn. The yarn 12 is flexible and can be incorporated into a textile like normal yarn. For example the yarn 12 can be woven into a fabric without substantially altering or affecting the textile properties of the fabric.

The yarn 12 has a cylindrical, flexible insulator 20 as a core. Around the insulator 20 two equally flexible conductive layers 30, 32 are arranged that extend along a longitudinal direction of the yarn 12. The conductive layers 30, 32 are designed in the form of half-shells and have a cross-section of approximately half a hollow cylinder. Via two intermediate spaces 34 extending along the longitudinal direction of the yarn 12 the conductive layers 30, 32 are separated and therefore insulated from each other.

A second embodiment of an extension sensor 10 according to the invention is shown in FIG. 3. In this embodiment the yarn 12 has a rectangular cross-section and is designed as a flat, elongate tape. The tape has a central, flexible insulator 20 which extends along the longitudinal direction of the tape. On an upper side and a lower side of the insulator 20 a conductive layer 30 and 32 respectively is arranged in each case, which also extend along the longitudinal direction of the tape. The conductive layers 30, 32 are also flexible.

In the embodiments according to FIGS. 1 to 3 the conductive layers 30, 32 are thin in comparison with the insulator 20, in which case the thickness differs at least by the factor 10.

An extension sensor 10 in the form of a coaxial yarn is illustrated in FIG. 4. The extension sensor 10 has a flexible yarn 12 with an approximately round cross-section, in the center of which a first conductive layer 30 is arranged. The first conductive layer 30 extends along a longitudinal direction of the yarn 12 and has a round cross-section. The first conductive layer 30 therefore has a cylindrical shape.

Around the first conductive layer 30 an insulator 20 in the form of a hollow cylinder is arranged. The insulator 20 is coated at its outer surface with a thin, second conductive layer 32.

FIG. 5 shows a cross-sectional view of an insulator 20, of which an extension sensor 10 according to the invention in the form of yarn can be produced in a particularly easy way. The insulator 20 has a substantially cylindrical shape with two groove-like notches 22 or cavities which extend opposite each other along a longitudinal direction of the insulator 20. Thus, on each side of the notches 22 approximately one cylinder half 26 is formed. The insulator 20 can be coated all around in a simple process. The notches 22 in the yarn cross-section have the effect that the coating is not constant throughout the inside of the notches 22. As a result, the coating is automatically divided into two halves that form the first conductive layer 30 and the second conductive layer 32.

The extension sensors 10 shown in FIGS. 1 to 5 are especially suitable for use as capacitive extension sensors.

A further embodiment of an extension sensor 10 is shown in FIG. 6. The extension sensor 10 comprises a yarn 12, which, just like the previously described extension sensors, has a flexible insulator 20 and two flexible, conductive layers 30, 32. In this embodiment the insulator 20 is of approximately cuboid design and having a rectangular cross-section. At two opposite surfaces of the insulator 20 two identically designed conductive layers 30, 32 are provided in each case, which each have an approximately semi-circular or arched cross-section. The insulator 20 and the semi-circular, conductive layers 30, 32 altogether form a yarn 12 with a circular cross-section. This yarn 12 is particularly suitable for use as a resistive extension sensor.

For use as a resistive extension sensor 10 the two conductive layers 30, 32 or halves of the yarn 12 have to be electrically connected to each other, i.e. short-circuited, at one end of the yarn 12 in order to form a closed circuit in conjunction with a measuring instrument to be connected. At the other end of the yarns 12 ohmic measurement of the resistance and therefore the extension can be made using a measuring instrument.

FIG. 7 shows a fabric as a textile 40, into which two yarns 12 are woven as measuring yarns. The remaining yarns 42 of the fabric are regular yarns, i.e. in particular non-conductive yarns.

The two yarns 12 each have a single conductive layer. For this purpose the yarns 12 can have a conductive coating or a conductive core. It is also possible that the yarns 12 consist in their entirety of a conductive material. In order that a measuring instrument 14, that is to be connected, does not have to contact two different edge regions or sides of the textile 40 and in order to increase the sensitivity of the measurement the two yarns 12 are electrically connected to each other at one end via a conductor link 44. By short-circuiting the two yarns 12 a closed circuit is formed in conjunction with the measuring instrument 14. By means of the measuring instrument ohmic measurement of the resistance can be made and therefore the extension can be measured. Together with the measuring instrument the yarn or yarns or respectively the textile with the yarns form a measuring means.

1. Extension sensor, in particular for measuring an extension of a textile,
wherein
at least one yarn is provided, which has an extensibility, and
the yarn comprises at least two electrically conductive layers, which extend along a longitudinal direction of the yarn, the electrically conductive layers being spatially separated and insulated from each other.

2. Extension sensor according to claim 1,
wherein
by means of the electrically conductive layers a capacitor is formed, the capacity of which changes in the case of an extension of the yarn due to a change of distance between the electrically conductive layers.

3. Extension sensor according to claim 1,
wherein
between the electrically conductive layers a conductor link is arranged, and
by means of the electrically conductive layers a conductor path is formed, the electrical resistance of which changes in the case of an extension of the yarn due to an elongation of the conductor path.

4. Extension sensor according to claim 1,
wherein
the yarn has a reversible extensibility.

5. Extension sensor according to claim 4,
wherein
the reversible extensibility amounts to 2 to 10%, preferably 5 to 10%, more preferably 2 to 5%.

6. Extension sensor according to claim 1,
wherein
the yarn has a round or rectangular cross-section.

7. Extension sensor according to claim 1,
wherein
the conductive layers each have an electrical resistance of 0.1 to 2 kOhm/m.

8. Extension sensor according to claim 1,
wherein
the conductive layers are each provided on an outer surface of the yarn.

9. Extension sensor according to claim 1,
wherein
the conductive layers are arranged coaxially to each other, wherein a first conductive layer is arranged in an inner region of the yarn and a second conductive layer is arranged in an outer region of the yarn.

10. Extension sensor according to claim 1,
wherein
a protective coating for protection against abrasion and/or humidity is present.

11. Extension sensor according to claim 1,
wherein
a textile is provided, into which the yarn is incorporated, in particular through weaving or knitting.

12. Method for measuring an extension of a textile,
wherein
at least one extensible yarn is made available, which comprises at least two electrically conductive layers that extend along a longitudinal direction of the yarn, in particular parallel to each other, wherein the electrically conductive layers are spatially separated and insulated from each other, and
for determining an extension of the textile a change of the capacity of a capacitor formed by the conductive layers or a change of the electrical resistance of a conductor path formed by the conductive layers is measured.

13. Method for measuring an extension of a textile,
wherein
at least two extensible yarns are made available, which each have an electrically conductive layer,
the yarns are incorporated into the textile,
on a first side of the textile a conductor link is arranged between the yarns so that a conductor path is formed by the yarns and
for determining an extension of the textile a change of the electrical resistance of the conductor path formed by the yarns is measured on a second side of the textile.

14. Method according to claim 13,
wherein
the extensible yarns are incorporated into the textile, in particular through weaving or knitting.
